(19) United States
(12) Patent Application Publication
(10) Pub. No.: US 2006/0003546 A1
(43) Pub. Date: Jan. 5, 2006

(54) Gap-filling for isolation

(76) Inventors: Andreas Klipp, Dresden (DE); Momtchil Stavrev, Dresden (DE); Moritz Haupt, Dresden (DE)

Correspondence Address: SLATER & MATSIL LLP, 17950 PRESTON ROAD, SUITE 1000, DALLAS, TX, 75252, US

(21) Appl. No.: 10/881,717

(22) Filed: Jun. 30, 2004

(51) Int. Cl. H01L 21/76

(52) U.S. Cl. 438/431; 438/432; 438/430; 438/424

(57) ABSTRACT

A method of filling high ratio trenches on a substrate is described. First, an oxidizable layer is deposited on the substrate. Thereafter, a trench fill oxide is deposited on the substrate and on the oxidizable layer. Afterwards, the resulting structure is annealed using an oxygen containing gas such that the oxidizable layer is oxidized.

### TECHNICAL FIELD

This invention relates generally to a method of filling high ratio gaps such as trenches on substrates used in the fabrication of semiconductor devices, wafers and the like.

### BACKGROUND

In order to physically and electrically separate electronic elements of a semiconductor device from one another, shallow insulating trenches are located therebetween. As semiconductor technology advances, semiconductor devices become more dense. Therefore, the width of the insulating trenches decreases, resulting in increasing “aspect ratios” (trench height/trench width) of the trenches. In consequence, trench filling with insulating materials such as oxides becomes more and more difficult. In order to avoid discontinuities or voids in the trench filling material, many approaches can be found in the literature.

The international patent application WO 00/60659, which is related to U.S. Pat. No. 6,387,764, discloses a trench isolation method, wherein a trench fill oxide layer is deposited on a substrate having trenches. Afterwards, a thermal oxide is grown on the sidewalls of the trench. According to this document, the trench fill is more likely to be void free, if the sidewalls of the trench are not covered by the trench fill oxide layer.

The U.S. Pat. No. 5,872,058 describes a method wherein an oxide film is deposited over trenches using a gas mixture with a reduced inert gas concentration. Due to the reduced inert gas concentration, the etch or sputter rate decreases and cusps do not form on the trench sidewalls, because less material is etched and thus available for redeposition. The trenches are therefore filled quite homogeneously.

Another method of filling trenches is described in the U.S. Pat. No. 5,726,090. This method comprises a step of growing a thermal oxide layer within the trenches. Then, a plasma enhanced SiH₄ oxide “underlayer” is deposited over the trenches and treated with N2-plasma. Thereafter, the trenches are filled with an ozone-TEOS (TEOS: Tetraethoxysilane)-oxide. The quality of the trench filling largely depends on how the “underlayer” is formed and treated.

Another gap fill technique uses a Spin-On-Glass (SOG) process by which a liquid is applied to the semiconductor structures, spun at high speed to distribute the material across the structures, and then heat treated to cure or stabilize the resultant film. This technique shows excellent gap fill capability but adversely suffers excessive shrinkage of the material due to the required heat treatment. The paper “The P-SOG Filling Shallow Trench Isolations Technology for sub-70 nm Device” (Jin-Hwa Heo, Soo-Jin-Hong, Guk-Hyon Yon, Yu-Gyun Shin, Kazuyuki Fujihara, U-In Chung, Joo-Tae Moon, 2003 Symposium on VLSI Technology Digest of Technical Paper, p. 155-156) describes such a trench isolation using P-SOG (Polysilazane-based inorganic Spin-On-Glass). After a CMP (chemical mechanical polishing)-process the P-SOG material is annealed.

In summary, the filling of trenches with a high aspect ratio is quite challenging. Most problems are caused by a shrinkage of the filling material which occurs when the material is annealed in a further process step.

### SUMMARY OF THE INVENTION

In one aspect, the invention provides a process for improving the gap filling characteristics of an isolation gap or trench.

In another aspect, the invention avoids discontinuities such as voids in the filling material.

In accordance with a preferred embodiment of the invention, an improved gap isolation method is achieved. An oxidizable layer is deposited on a substrate having gaps with sidewalls. Thereafter, a gap fill oxide is deposited on the substrate and on the oxidizable layer. Then, the resulting structure is annealed using an oxygen containing gas such that the oxidizable layer is oxidized.

The key aspect of the present invention is the use of an additional oxidizable layer. As stated above, many problems with respect to the filling of gaps are caused by the shrinkage of the gap fill oxide during further process steps, which results in unwanted voids. As the “buried” oxidizable layer according to the invention is oxidized, its volume increases and fills up the space that is left empty by the shrinking gap fill oxide. In consequence, the effect of shrinkage of the gap fill oxide is compensated by the increasing layer thickness of the buried “oxidized-layer”. In other words, the oxidizable layer is sacrificed in order to produce an oxide that fills up voids otherwise left empty due to the shrinkage of the gap fill oxide.

In order to achieve as less material tension as possible, the thickness of the oxidizable layer is preferably chosen such that its volume increase during oxidation corresponds to the estimated shrinkage of the gap fill oxide during the anneal step.

The gaps may be formed as trenches, e.g., in order to separate electrical devices from one another.

Preferably, the oxidizable layer is a semiconductor layer forming a semiconductor oxide.

According to a preferred embodiment of the invention, the semiconductor layer is a silicon layer—preferably an amorphous silicon layer. A silicon layer is advantageous as it forms a silicon oxide layer during the following anneal step. As silicon oxide is usually also used as the gap fill oxide, the “sacrificial silicon layer” is fully incorporated into the gap fill oxide during the anneal step.

According to another preferred embodiment of the invention, an oxide liner is deposited on the sidewalls of the gaps prior to the depositing of the semiconductor layer. Accordingly, a kind of sandwich structure is formed with the semiconductor layer therein. Preferably, also prior to the depositing of the semiconductor layer, the oxide liner is etched such that the thickness of the remaining liner is larger next to the bottom of the gaps than next to the top of the gaps. For example, the oxide liner may be approximately V-shaped in cross section.

The oxide liner and/or the gap fill oxide may be of any kind. For example, the oxide liner and/or the gap fill oxide may be a Spin-On-Glass as mentioned above in connection with prior art. Alternatively, both oxides can be deposited using a process gas. Preferably, the oxide liner and/or the gap fill oxide are deposited using a process gas containing Tetraethylorthosilane or Tetraethyoxysilane. The deposition process may be a LPTEOS- or a ozone-TEOS (O3-TEOS) process.

According to another preferred embodiment of the invention, the step of annealing is carried out in a steam environment as a steam environment enhances the oxidation rate of the semiconductor layer.

### BRIEF DESCRIPTION OF THE DRAWINGS

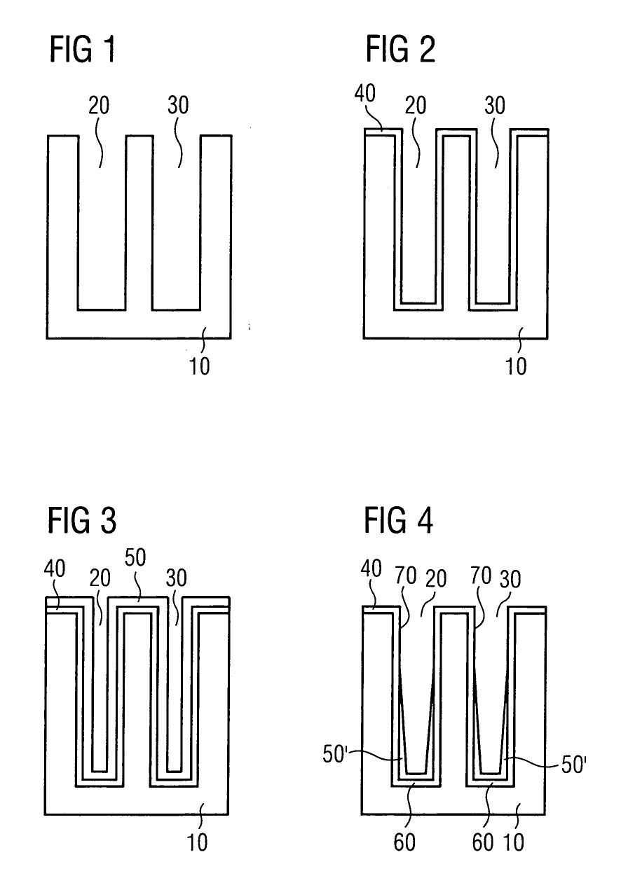

Other advantages of the invention become apparent upon reading of the detailed description of the invention, and the appended claims provided below, and upon reference to the drawings, in which FIGS. 1 to 7 illustrate an example of an isolation process according to the invention.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

FIG. 1 shows a silicon substrate 10 having two trenches 20 and 30. The trenches are etched in a usual way, e.g., using an oxide or nitride hard mask. An SiN-liner (i.e., layer) 40 is deposited on the substrate 10 and on the trenches 20 and 30 (FIG. 2). The SiN-liner 40 protects the underlying silicon structure and makes sure that the silicon structure cannot be oxidized in further process steps.

On top of the SiN-liner 40, a conformal oxide liner 50, preferably a TEOS-based oxide liner, is deposited. The resulting structure is shown in FIG. 3. The process parameters of the oxide liner 50 may be as follows:

| | | |
|---|---|---|
| Temperature: | 620-650° | C. |
| Pressure: | 200-1000 | mTorr |
| TEOS Flow: | 80-200 | sccm |
| N₂ Flow: | 50-150 | sccm |
| O₂ Flow: | 50-100 | sccm |
| deposition rate: | 1-2.5 | nm/min |

The conformal oxide liner 50 is subjected to a polymerizing etch process wherein the liner material of the oxide liner 50 is etched such that the remaining liner 50′ is thicker next to the bottom 60 of the trenches 20 and 30 rather than next to the top 70 of the trenches. The cross section of the remaining liner 50′ is basically V-shaped as shown in FIG. 4. Suitable process parameters of the etch process are as follows:

| | | |
|---|---|---|
| Temperature: | 40-60° | C. |
| Plasma Power: | 300-700 | W |
| Pressure: | 20-50 | mTorr |
| Ar Flow: | 400-500 | sccm |
| C₅F₈ Flow: | 4-8 | sccm |
| O₂ Flow: | 1-3 | sccm |

Further details on how a V-shaped profile can be achieved, are described in the paper “Trench Shaping through Wafer Temperature Control” (K. P. Müller, K. Roithner, Electrochemical Society Proceedings of the Second International Symposium, 1995, 266-271), which paper is incorporated herein by reference.

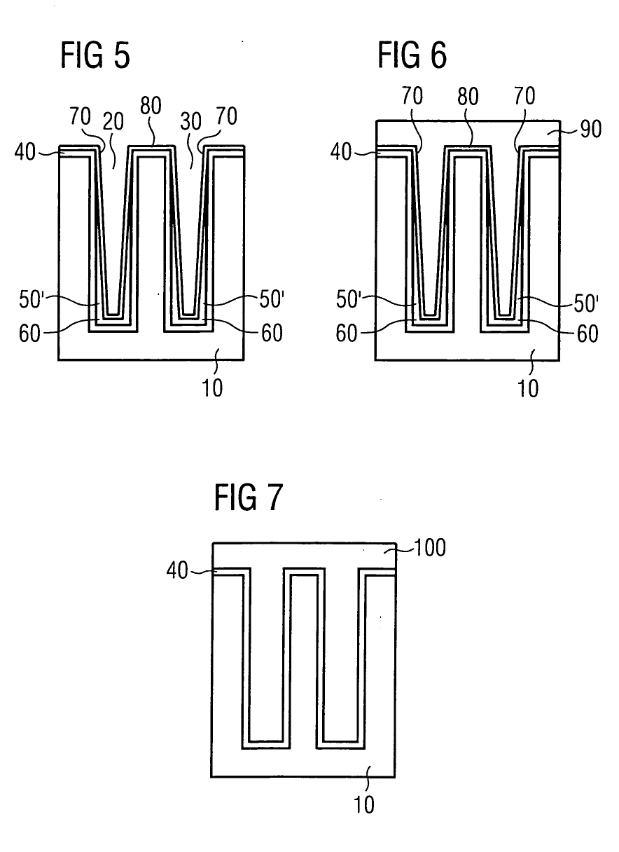

On top of the V-shaped oxide liner 50′ an a-Si-layer 80 is deposited as a “sacrificial layer” (FIG. 5). The function of this a-Si-layer 80 will be explained in detail further below. The process parameters for depositing the a-Si-layer 80 may be chosen as follows:

| | | |
|---|---|---|
| Temperature: | 500-535° | C. |
| Pressure: | 600-1400 | mTorr |
| SiH₄-Top-: | 50-100 | sccm |
| SiH₄-Bottom-: | 150-300 | sccm |
| Deposition Rate: | 0.5-1.25 | nm/min |

In a following deposition step, a trench fill oxide 90 based on TEOS-oxide is deposited on the substrate 10, thereby filling the trenches 20 and 30 (FIG. 6). Suitable process parameters for depositing the trench fill oxide 90 are as follows:

| | | |
|---|---|---|
| Temperature: | 620-680° | C. |
| Pressure: | 600-1000 | mTorr |
| TEOS Flow: | 80-200 | sccm |
| N₂ Flow: | 50-150 | sccm |
| O₂ Flow: | 50-100 | sccm |
| Deposition Rate: | 1-4 | nm/min |

Thereafter, an anneal step is carried out in a steam atmosphere. During this anneal step, the buried a-Si-layer 80 is oxidized, preferably completely, and forms—together with the trench fill oxide 90—a uniform oxide layer 100 (FIG. 7).

During the anneal step, the a-Si-layer 80, the oxide liner 50′ and the trench fill oxide 90 behave differently. Both oxides layers 50 and 90 will shrink. In contrast thereto, the a-Si-layer 80 will grow in thickness as the layer oxidizes. In consequence, the voids that would usually result in the trench fill oxide 90 due to its shrinkage, are filled by the oxidizing “sacrificial layer” 80. In other words, the compressing force of the oxidized “sacrificial layer” 80 compensates the decompressing force of the shrinking trench fill oxide 90. As a result, the uniform oxide layer 100 is free of internal voids and internal seams. The process parameters for the “steam anneal step” may be as follows:

| Temperature: | 900 +/− 100° C. |
|---|---|
| Steam Content —O₂/H₂— = 1:1 to 1:1,6 | |
| Anneal Time: | 10-30 min |

Although the present invention and its advantages have been described in detail, it should be understood that various changes, substitutions and alterations can be made herein without departing from the spirit and scope of the invention as defined by the appended claims.

What is claimed is:

1. A method for filling a gap during integrated circuit production, the method comprising:
depositing an oxidizable layer on a substrate having a gap with sidewalls;
depositing a gap fill oxide over said substrate and over said oxidizable layer; and
annealing the resulting structure using an oxygen containing gas such that the oxidizable layer is oxidized.

2. Method according to claim 1, wherein the thickness of said oxidizable layer is chosen such that its increase during oxidation corresponds to an estimated shrinkage of the gap fill oxide during the anneal step.

3. Method according to claim 2, wherein said oxidizable layer comprises a semiconductor layer.

4. Method according to claim 3, wherein said semiconductor layer comprises a silicon layer and wherein the silicon layer is oxidized to form silicon oxide during the anneal step.

5. Method according to claim 4, wherein the silicon layer comprises an amorphous silicon layer.

6. Method according to claim 5, and further comprising depositing an oxide liner over said substrate prior to depositing said amorphous silicon layer.

7. Method according to claim 6, wherein said oxide liner is etched such that the remaining liner is thicker next to a bottom of the gap than next to a top of the gap.

8. Method according to claim 7, wherein said oxide liner is approximately V-shaped in cross section.

9. Method according to claim 8, wherein said oxide liner and/or said gap fill oxide is deposited using a process gas containing Tetraethylorthosilane or Tetraethyoxysilane.

10. Method according to claim 9, wherein said oxide liner and/or said gap fill oxide is deposited using a LPTEOS-process.

11. Method according to claim 10, wherein said anneal step is carried out in a steam environment.

12. Method according to claim 1, and further comprising depositing an oxide liner over said substrate prior to depositing said oxidizable layer.

13. Method according to claim 12, wherein said oxide liner is etched such that the thickness of the remaining liner is larger next to a bottom of the gap than next to a top of the gap.

14. Method according to claim 13, wherein said oxide liner is approximately V-shaped in cross section.

15. Method according to claim 14, wherein said oxide liner and/or said gap fill oxide is deposited using a process gas containing Tetraethylorthosilane or Tetraethyoxysilane.

16. Method according to claim 15, wherein said step of annealing is carried out in a steam environment.

17. Method according to claim 1, wherein said anneal step is carried out in a steam environment.

18. Method according to claim 1, wherein the gap is formed as a trench.

19. Method according to claim 18, wherein the gap comprises an isolation trench formed in a silicon substrate.

20. Method according to claim 1, wherein the substrate comprises a plurality of gaps and wherein depositing an oxidizable layer comprises depositing an oxidizable layer over each of the gaps and wherein depositing a gap fill oxide comprises filling each of the gaps.
